(19) United States
(12) Patent Application Publication
(10) Pub. No.: US 2014/0332374 A1
(43) Pub. Date: Nov. 13, 2014

(54) STABLE PHOTOELECTRODE SURFACES AND METHODS

(71) Applicant: Alliance for Sustainable Energy, LLC, Golden, CO (US)

(72) Inventors: Todd DEUTSCH, Westminster, CO (US); John TURNER, Broomfield, CO (US); Jennifer LEISCH, Washington, DC (US); Heli WANG, Littleton, CO (US); Adam WELCH, Lakewood, CO (US); Avery LINDEMAN, Berkeley, CA (US); Kevin O'NEILL, Boulder, CO (US); Andrew PINKARD, Vista, CA (US); Arrelaine DAMERON, Boulder, CO (US); Clemens HESKE, Las Vegas, NV (US); Kyle GEORGE, Las Vegas, NV (US); Lothar WEINHARDT, Karlsruhe (DE); Michael WEIR, Las Vegas, NV (US)

(73) Assignee: Alliance for Sustainable Energy, LLC, Golden, CO (US)

(21) Appl. No.: 14/276,425

(22) Filed: May 13, 2014

Related U.S. Application Data
(60) Provisional application No. 61/822,744, filed on May 13, 2013.

(51) Int. Cl. H01G 9/20; H01L 21/283; H01L 21/265

(52) U.S. Cl. CPC H01G 9/205; H01L 21/26553; H01L 21/283
USPC 204/242; 438/523; 204/290.14

(57) ABSTRACT

Disclosed herein are methods of treating a semiconductor surface by nitridation and deposition of a ruthenium alloy. Also disclosed are semiconductors treated with these methods, their incorporation into photoelectrochemical cells, and their use in photoelectrochemical water splitting.

### CROSS-REFERENCE TO RELATED APPLICATIONS

This application claims the benefit of priority under 35 U.S.C. §119 (e) from U.S. Provisional Application Ser. No. 61/822,744 filed on May 13, 2013, the contents of which are incorporated by reference herein in their entirety.

### CONTRACTUAL ORIGIN

The United States Government has rights in this invention under Contract No. DE-AC36-08G028308 between the United States Department of Energy and Alliance for Sustainable Energy, LLC, the Manager and Operator of the National Renewable Energy Laboratory.

### BACKGROUND

Hydrogen exhibits the potential to be an emission-free fuel that can be produced from abundant resources found throughout the world. The development of fuel cell vehicles, for example, could reduce the supply needs, pollution effects, and other problems associated with petroleum-based transportation fuels. To become a viable energy option, however, hydrogen must be produced economically from sustainable sources.

Currently, steam reforming of natural gas accounts for most of the hydrogen produced in the United States. A cleaner and more sustainable way to produce hydrogen is to use sunlight to directly split water into hydrogen and oxygen. Such photoelectrochemical (PEC) devices combine a light harvesting system with a water splitting system, the latter comprising a semiconductor immersed in an aqueous electrolyte solution. The semiconductor materials currently used in light-harvesting systems, however, are subject to corrosion resulting from prolonged operation under illumination in harsh aqueous electrolytes.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be illustrative and not limiting in scope. In various embodiments, one or more of the above-described problems have been reduced or eliminated, while other embodiments are directed to other improvements.

In a first aspect, methods of treating an exposed semiconductor surface are disclosed, the methods comprising implanting nitrogen ions in an exposed semiconductor surface, and depositing a ruthenium alloy on the exposed semiconductor surface.

In some embodiments, the ruthenium alloy comprises ruthenium and platinum.

In some embodiments, the ruthenium alloy comprises ruthenium and platinum at a 50:50 ratio.

In some embodiments, the ruthenium alloy is deposited in a submonolayer amount.

In some embodiments, the ruthenium alloy is deposited as nanoparticles along the exposed surface of the semiconductor.

In some embodiments, the nanoparticles are about 2-5 nm in diameter.

In some embodiments, the semiconductor comprises a Group III-V semiconductor.

In some embodiments, the Group III-V semiconductor comprises GaInP₂.

In some embodiments, the Group III-V semiconductor comprises p-type GaInP₂.

In some embodiments, the Group III-V semiconductor comprises InP.

In some embodiments, the Group III-V semiconductor comprises p-type InP.

In some embodiments, the step of depositing is conducted by sputtering.

In some embodiments, the step of implanting and the step depositing are conducted in the same chamber.

In a second aspect, photoelectrodes comprising a nitrided semiconductor and a submonolayer amount of a ruthenium alloy in contact with at least one surface of the nitrided semiconductor are disclosed.

In some embodiments, the ruthenium alloy comprises ruthenium and platinum.

In some embodiments, the ruthenium alloy comprises ruthenium and platinum at a 50:50 ratio.

In some embodiments, the ruthenium alloy is deposited as nanoparticles.

In some embodiments, the nanoparticles are about 2-5 nm in diameter.

In some embodiments, the semiconductor is a Group III-V semiconductor.

In some embodiments, the Group III-V semiconductor comprises GaInP₂.

In some embodiments, the Group III-V semiconductor comprises p-type GaInP₂.

In some embodiments, the Group III-V semiconductor comprises InP.

In some embodiments, the Group III-V semiconductor comprises p-type InP.

In a third aspect, photoelectrochemical cells are provided, the photoelectrochemical cells comprising a photoelectrode, the photoelectrode comprising a nitrided semiconductor, and a submonolayer amount of a ruthenium alloy in contact with at least one surface of the nitrided semiconductor.

In some embodiments, the ruthenium alloy comprises ruthenium and platinum.

In some embodiments, the ruthenium alloy comprises ruthenium and platinum at a 50:50 ratio.

In some embodiments, the ruthenium alloy is deposited as nanoparticles.

In some embodiments, the nanoparticles are about 2-5 nm in diameter.

In some embodiments, the semiconductor is a Group III-V semiconductor.

In some embodiments, the Group III-V semiconductor comprises GaInP₂.

In some embodiments, the Group III-V semiconductor comprises p-type GaInP₂.

In some embodiments, the Group III-V semiconductor comprises InP.

In some embodiments, the Group III-V semiconductor comprises p-type InP.

In some embodiments, the photoelectrochemical further comprises a substrate in contact with the photoelectrode.

In some embodiments, the photoelectrochemical further comprises an ohmic contact in contact with the substrate.

In some embodiments, the photoelectrochemical further comprises a counter electrode in electrical contact with the photoelectrode.

In a fourth aspect, multijunction cells are provided, the multijunction cells comprising a photoelectrode, the photoelectrode comprising a nitrided semiconductor and a submonolayer amount of a ruthenium alloy in contact with at least one surface of the nitrided semiconductor.

In some embodiments, the ruthenium alloy comprises ruthenium and platinum.

In some embodiments, the ruthenium alloy comprises ruthenium and platinum at a 50:50 ratio.

In some embodiments, the ruthenium alloy is deposited as nanoparticles.

In some embodiments, the nanoparticles are about 2-5 nm in diameter.

In some embodiments, the semiconductor is a Group III-V semiconductor.

In some embodiments, the Group III-V semiconductor comprises GaInP₂.

In some embodiments, the Group III-V semiconductor comprises p-type GaInP₂.

In some embodiments, the Group III-V semiconductor comprises InP.

In some embodiments, the Group III-V semiconductor comprises p-type InP.

In a fifth aspect, methods of generating hydrogen from water are provided, the methods comprising illuminating the photoelectrode of a photoelectrochemical cell with light, the photoelectrochemical cell comprising a photoelectrode, the photoelectrode comprising a nitrided semiconductor and a submonolayer amount of a ruthenium alloy in contact with at least one surface of the nitrided semiconductor; wherein the photoelectrode is in contact with an aqueous electrolyte and wherein the photoelectrode splits water from the aqueous electrolyte into hydrogen and oxygen, and isolating the generated hydrogen.

In some embodiments, the ruthenium alloy comprises ruthenium and platinum.

In some embodiments, the ruthenium alloy comprises ruthenium and platinum at a 50:50 ratio.

In some embodiments, the ruthenium alloy is deposited as nanoparticles.

In some embodiments, the nanoparticles are about 2-5 nm in diameter.

In some embodiments, the semiconductor is a Group III-V semiconductor.

In some embodiments, the Group III-V semiconductor comprises GaInP₂.

In some embodiments, the Group III-V semiconductor comprises p-type GaInP₂.

In some embodiments, the Group III-V semiconductor comprises InP.

In some embodiments, the Group III-V semiconductor comprises p-type InP.

In some embodiments, the photoelectrochemical cell further comprises a substrate in contact with the photoelectrode.

In some embodiments, the photoelectrochemical cell further comprises an ohmic contact in contact with the substrate.

In some embodiments, the photoelectrochemical cell further comprises a counter electrode in electrical contact with the photoelectrode.

In addition to the examples of aspects and embodiments described above, further aspects and embodiments will become apparent by reference to the drawings and by study of the following descriptions.

### BRIEF DESCRIPTION OF THE DRAWINGS

Examples of embodiments are illustrated in referenced figures of the drawings. It is intended that the embodiments and figures disclosed herein are to be considered illustrative rather than limiting.

FIG. 1 shows a photoelectrochemical cell with a GaInP₂/GaAs tandem cell system, in accordance with embodiments disclosed herein.

FIG. 2 shows a model of a surface of a GaInP₂ semiconductor subjected to ion implantation and deposition in relation to a photo-inactive GaAs substrate and gold (Au) ohmic contact.

FIG. 3A shows the surface of an untreated p-GaInP₂ electrode after 24 hours of exposure to 3M H₂SO₄ electrolyte while passing a constant current of 10 mA/cm² through the electrode.

FIG. 3B shows the surface of a p-GaInP₂ electrode that has been treated in accordance with the methods disclosed herein, after 24 hours of exposure to 3M H₂SO₄ electrolyte while passing a constant current of 18.5 mA/cm² through the electrode.

FIG. 4A shows the results of optical (interference) profilometry for an untreated GaInP₂ electrode after 24 hours of exposure to 3M H₂SO₄ electrolyte while passing a current of 10 mA/cm² through the electrode.

FIG. 4B shows the results of optical (interference) profilometry for a GaInP₂ electrode that has been treated in accordance with the methods disclosed herein, after 24 hours of exposure to 3M H₂SO₄ electrolyte while passing a current of 18.5 mA/cm² through the electrode.

FIG. 5 shows the Incident Photon-to-Current Efficiency (IPCE) of electrodes treated in accordance with the methods disclosed herein, before and after durability testing.

FIG. 6 shows the amount of gallium and indium in solution for untreated electrodes (A1-A4), and electrodes made from two separate treatment runs of p-GaInP₂ (B1-B3) and (C1-C3) in accordance with the methods disclosed herein, as detected by ICP-MS.

FIG. 7A shows chopped-light, three-electrode J-V data taken in 3M H₂SO₄ with light calibrated to AM 1.5G before and after durability testing for untreated electrodes.

FIG. 7B shows chopped-light, three-electrode J-V data taken in 3M H₂SO₄ with light calibrated to AM 1.5G before and after durability testing for treated electrodes.

FIG. 8A shows the surface of an untreated p-InP electrode after 24 hours of exposure to 3M H₂SO₄ electrolyte while passing a constant current of 25 mA/cm² through the electrode.

FIG. 8B shows the surface of a p-InP electrode that has been treated according to the methods disclosed herein, after 24 hours of exposure to 3M H₂SO₄ electrolyte while passing a constant current of 25 mA/cm² through the electrode.

FIG. 9A shows the results of optical (interference) profilometry for an untreated p-InP electrode after 24 hours of exposure to 3M H₂SO₄ electrolyte while passing a current of 25 mA/cm² through the electrode.

FIG. 9B shows the results of optical (interference) profilometry for a p-InP electrode that has been treated according to the methods disclosed herein, after 24 hours of exposure to 3M H₂SO₄ electrolyte while passing a current of 25 mA/cm² through the electrode.

FIG. 10 is a bar graph that shows the concentration of indium present in 3M H₂SO₄ durability solutions as detected by ICP-MS for InP untreated and treated electrodes.

FIG. 11 is a graph of true short circuit zero-bias photocurrent density vs. time for a standard GaInP₂/GaAs tandem with platinum electrodeposited on its surface, and a nitrogen ion implanted and PtRu sputtered GaInP₂/GaAs tandem.

### DETAILED DESCRIPTION

Disclosed herein are methods of treating a semiconductor surface that result in the stabilization of the semiconductor material when placed in contact with an electrolyte. In general, the methods comprise an ion implantation step of bombarding the semiconductor surface with nitrogen (N₂⁺) ions and a deposition step of placing small amounts of a ruthenium alloy on the semiconductor surface. Semiconductors treated with these methods exhibit enhanced resistance to corrosion resulting from constant illuminated operation in acidic electrolytes. Treated semiconductors may also be used for high-efficiency photoelectrochemical water splitting.

Nitrogen may be introduced into the semiconductor material by subjecting the semiconductor to ion bombardment with nitrogen ions (e.g., low-energy nitrogen ions). Nitrogen ion bombardment may be conducted by placing the semiconductor material on a stage or wheel in an evacuated chamber into which a base pressure of nitrogen gas has been introduced. The sample may then be subjected to a stream of nitrogen ions from an ion gun. For example, an electrical potential may be used to ionize nitrogen gas and then accelerate the nitrogen ions toward the semiconductor target.

Ion bombardment is one means to nitridate a sample, but other methods may be used, including plasma nitridation processes. Additional suitable processes include low-temperature nitridation processes such as decoupled plasma nitridation (DPN), slot plane antenna (SPA) nitridation and jetvapor nitridation (JVN).

At least one surface of the semiconductor material may also be coated with a submonolayer amount of an alloy comprising ruthenium (such as, for example, a Pt/Ru alloy), or materials comprising alloys of ruthenium. Without wishing to be bound by any particular theory, it is believed that the alloys such as Pt/Ru are present in nanoparticle form on the surface of the semiconductor, rather than chemically bound to the surface. As used herein, a “submonolayer amount” is an amount of material placed in contact with an exposed surface of a semiconductor that does not completely cover the exposed surface. Any amount of alloy less than a monolayer may be deposited on the semiconductor surface. In various embodiments, less than 10%, 20%, 30%, 40%, 50%, 60%, 70%, 80%, or 90% of the semiconductor surface is coated with the alloy.

The relative amounts of ruthenium and additional components, such as platinum, in the alloy may also be varied. Typically, the alloy will contain no less than 10 or 20% of each element. Examples include alloys with at least 10-90% ruthenium, such as alloys containing at least 10%, 20%, 30%, 40%, 50%, 60%, 70%, 80%, or 90% ruthenium. Suitable Ru/Pt alloys include those with a Ru:Pt ratio of about 10:90, 20:80, 30:70, 40:60, 50:50, 60:40, 70:30, 80:20, or 90:10. Alloy components are expressed in terms of molar percentages and molar ratios of each element.

The alloy may be deposited on the semiconductor surface as nanoparticles that range in size from 1 to 100 nm. In certain embodiments, the alloys may be present on the semiconductor surface as nanoparticles ranging in size from about 1 to 10 nm or 2 to 5 nm. Examples of nanoparticles include those that are less than 50 nm, less than 45 nm, less than 40 nm, less than 35 nm, less than 30 nm, less than 25 nm, less than 20 nm, less than 15 nm, or less than 10, 9, 8, 7, 6, 5, 4, 3, 2 or 1 nm in size.

Any method for depositing a thin layer or submonolayer amount of material may be used to deposit the alloy on the semiconductor surface, including, without limitation, chemical and physical deposition methods. Examples of chemical deposition methods include chemical vapor deposition (CVD) techniques such as metalorganic CVD (MOCVD) or plasma enhanced CVD (PECVD) as well as spin coating, electrochemical deposition and atomic layer deposition. Suitable physical deposition techniques include pulsed laser deposition, electron beam physical vapor deposition and sputtering, such as ion-beam sputtering and reactive sputtering.

In certain embodiments, the semiconductor comprises at least one element from Group IIIA and at least one element from Group VA of the periodic table of elements (a “Group III-V semiconductor”), which may be p-type or n-type. Group III-V semiconductors are compound semiconductors that comprise at least one element from Group IIIA of the periodic table (e.g., boron (B), aluminum (Al), gallium (Ga), indium (In) or thallium (Tl)) and at least one element from Group VA of the periodic table (e.g., nitrogen (N), phosphorous (P), arsenic (As), antimony (Sb) or bismuth (Bi)). The Group III element and the Group V element are typically combined in such a way that the alloy contains about 50 atomic percent of the Group III element and about 50 atomic percent of the Group V element.

Group III-V semiconductors may also comprise more than one element from either Group III or Group V or from both groups. Such multinary compounds may have variable compositions according to the general formulas InₓGa₁₋ₓN, GaₓIn₁₋ₓP, InₓGa₁₋ₓP₁₋ₓN_{y}, AlₓIn_{y}Ga_{1-x-y}P, etc. Examples include binary alloys such as gallium arsenide (GaAs), ternary alloys such as gallium indium phosphide (GaInP₂) or quaternary alloys such as aluminum indium gallium phosphide (AlInGaP₃). Examples of III-V semiconductors include InP, GaP, InN, GaN, InGaN, GaNSb, InN, GaAsBi, GaPN, and InGaPN. In many embodiments, semiconductors comprising arsenides as a class may be protected according to the methods disclosed herein.

Semiconductors may also be doped with trace impurities (p- or n-type dopants) to alter the electrical properties of the semiconductor. The proper dopant will vary with the semiconductor used, and whether the semiconductor is p- or n-type. Semiconductors are typically doped in the range of 10¹⁷ to 10¹⁸ cm⁻³. Examples of n-type dopants include selenium and silicon. Examples of p-type dopants include zinc.

The semiconductor to be treated may be a stand-alone material or may include, among other things, a substrate. Many semiconductor materials are synthesized via growth on a substrate (e.g., using epitaxy) and the combined substrate and semiconductor may be utilized together with items such as photovoltaic cells or photoelectrochemical cells. Other technologies such as epitaxial lift off allow semiconductor layers to be grown on a substrate, but then allow the semiconductor to be removed from the substrate and used as an independent layer.

A wide range of substrates exist and a proper substrate may be chosen based on factors such as the semiconductor material to be grown on the substrate or the end use of the semiconductor (e.g., in a tandem solar cell), among others. The substrate may also be a p- or n-type semiconductor material, but may also be a noncrystalline substrate such as glass. Examples of substrates include gallium arsenide (GaAs), indium phosphide (InP) and other Group III-V semiconductors, silicon, silicon carbide (SiC), metal or metalloid oxides (e.g., of silicon), alloys, glass, and sapphire.

As used herein, epitaxy, epitaxial and epitaxially are generally defined as relating to the process where one crystalline substance is grown or deposited on another crystalline substance in an ordered manner. Depending upon the structure of the material grown and the substrate, an epitaxial process may feature more or less of a lattice match between a layer and the growth substrate. As used herein in relation to epitaxial processes, “grown” and “grow” are synonymous with “deposited” and “deposit.” Heteroepitaxy is a kind of epitaxy performed with materials that are different from each other. Various techniques are known for causing epitaxial growth, including but not limited to vapor-phase epitaxy (VPE), liquid phase epitaxy (LPE), molecular beam epitaxy (MBE), metal organic chemical vapor deposition (MOCVD) and others. The methods disclosed herein are not limited to any particular epitaxy method.

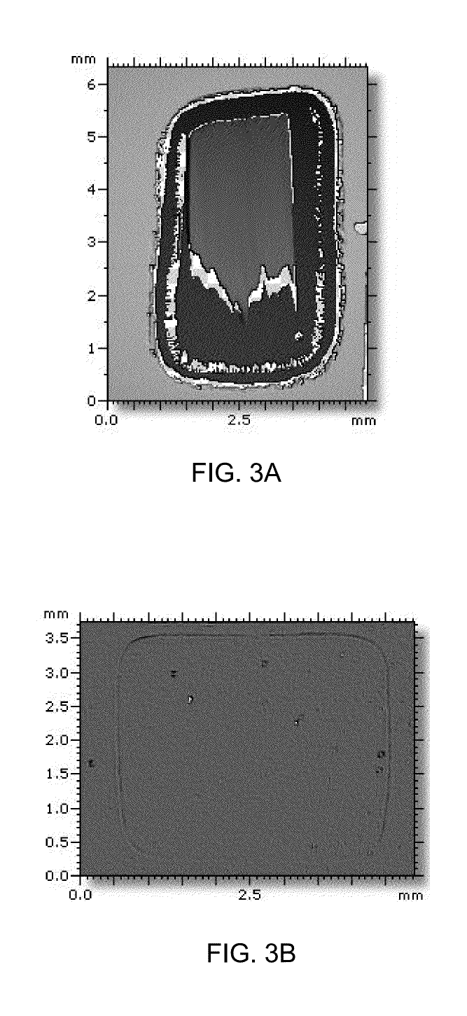

The semiconductor materials treated using the disclosed methods exhibit an increased durability or resistance to corrosion under illumination in the often harsh electrolytes used in devices such as photoelectrochemical cells, when compared to untreated semiconductor materials. Durability or corrosion resistance refers to the ability of a material to resist etching or degradation upon prolonged operation under illumination in a solution such as an electrolyte. Durability may be assessed by any method that identifies degradation or structural defects in a substance. For example, the surface of an electrode may be examined by microscopic techniques to examine whether the surface has been etched or degraded. Examples of microscopic techniques include optical microscopy, electron microscopy or interference microscopy (optical profilometry). Examples of microscopic images of treated and untreated electrode surfaces are shown in FIG. 3.

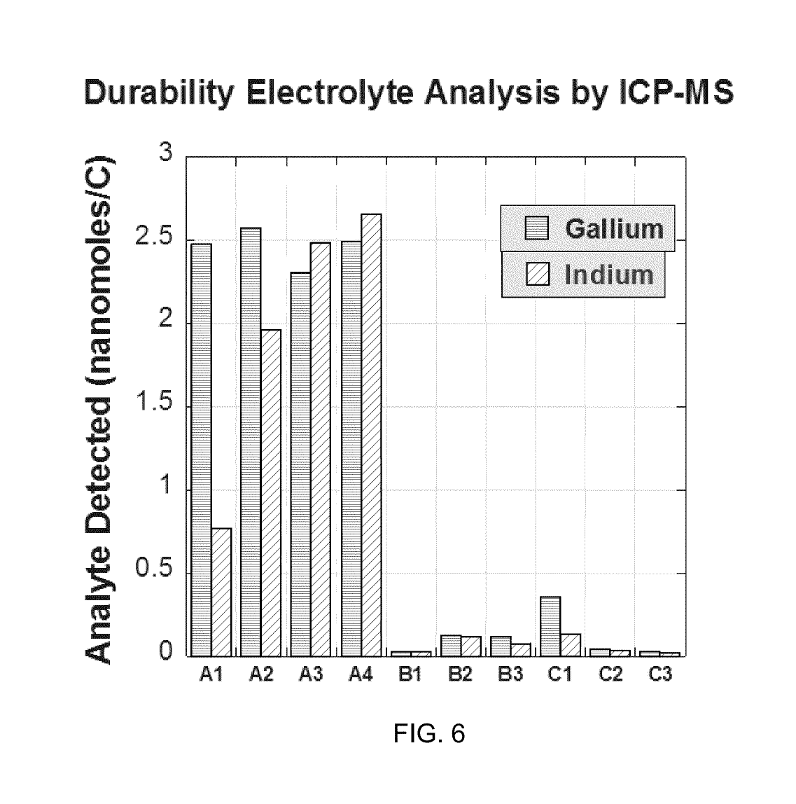

Durability may also be assessed by assay for the presence of semiconductor materials in an electrolyte solution before and after placing the semiconductor in contact with the electrolyte (e.g., in a photoelectrochemical cell or by running a current through the semiconductor while immersed in electrolyte). For example, the concentration of gallium or indium in an electrolyte can be quantified using techniques such as inductively coupled plasma mass spectrometry (ICP-MS), as shown in Example 4 and FIG. 6. Comparing the amount of a semiconductor component in an electrolyte before and after exposure of the semiconductor to the electrolyte allows one to quantify the amount of degradation induced by the electrolyte. Results may be normalized to the volume of electrolyte in a cell, the area of a semiconductor material, and the charge passed through the semiconductor material.

In addition to enhanced durability, treated semiconductors may exhibit increased efficiency when compared to untreated semiconductors. Treated semiconductors may exhibit increases in efficiency ranging from zero to thirty percent as determined by the light-limited photocurrent of a treated sample compared with an untreated sample. In certain embodiments, treated semiconductors may exhibit an increase in efficiency of at least about 5%, 10%, 15%, 20% or 25% in comparison to untreated semiconductors. Treated semiconductors may also exhibit minimal losses (e.g., less than 10%, less than 5% or less than 1%) in efficiency or no change in efficiency compared to untreated semiconductors.

The efficiency or performance of a semiconductor may be determined by methods such as determining the amount of photocurrent generated by the semiconductor upon illumination. For example, the semiconductor may be illuminated with calibrated white light and the magnitude of the light-limited photocurrent may then be determined, which is directly proportional to its photoconversion efficiency. The wavelength-dependent efficiency can also be determined by measuring the photocurrent generated under monochromatic light and comparing it to the response of a calibrated photodiode in a technique known as incident photon-to-current efficiency (IPCE). Comparison of the results for untreated and treated samples before and after extended exposure to an electrolyte allows for the assessment of the relative performance or efficiency of the semiconductor.

The semiconductor material described herein may be used as photoactive components in devices that can split water into hydrogen and oxygen spontaneously upon illumination (i.e., a photoelectrochemical cell, or PEC cell). The semiconductors treated using the methods herein are more resistant to corrosion induced by the harsh electrolytes commonly used in PEC cells, yet maintain efficient conversion of light to hydrogen and oxygen.

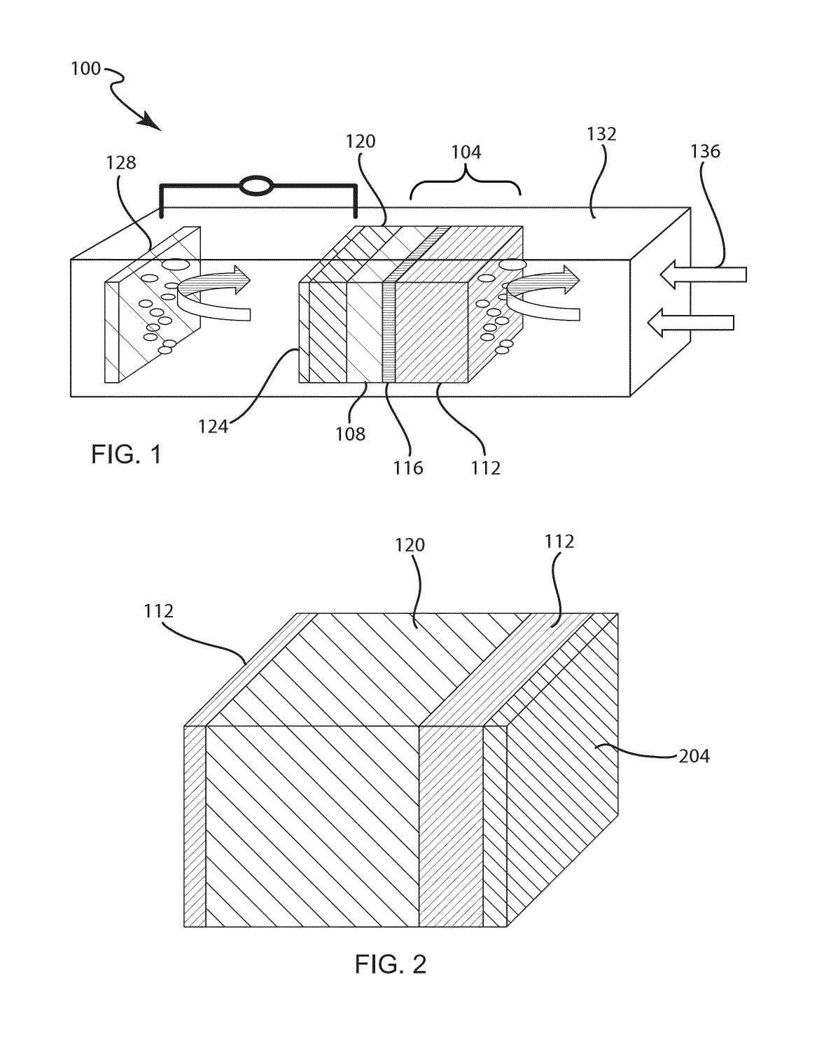

FIG. 1 illustrates the components of a PEC cell 100 in accordance with embodiments disclosed herein. In general, PEC cells comprise one or more photoactive semiconductor layers 104, an ohmic contact 124, and a counter electrode 128, all immersed in an electrolyte solution 132. As shown in FIG. 1, the photoactive semiconductor layers 104 may include a tunnel junction layer 116 disposed between a first photoactive semiconductor layer 108 and a second photoactive semiconductor layer 112. The photoactive semiconductor layers 104 are also typically in contact with a substrate layer 108. In some implementations, the first photoactive semiconductor layer 108 may include an n-type semiconductor, and the second photoactive semiconductor layer 112 and the substrate layer 120 may include a p-type semiconductor. The first photoactive semiconductor layer 108 and the substrate layer 120 may comprise, for example, GaAs. The second semiconductor layer 112 may comprise, for example, GaInP₂ or InP.

As shown in FIG. 1, the semiconductor/electrolyte interface may be illuminated with light 136, resulting water being split by reduction of water into hydrogen at the photocathode and by oxidation of water into oxygen at a dark anode. As illustrated in FIG. 2, the surface of the second semiconductor layer 112, which interfaces with the electrolyte 132 in the PEC cell 100, may be treated with the ion implantation and deposition as described herein. This ion implantation and deposition is illustrated in FIG. 2 and is generally indicated with reference number 204. Also shown in FIG. 2 are the substrate layer 120 and the gold ohmic contact 124 connected to the substrate 120. It should be appreciated that for purposes of simplifying FIG. 2, certain elements, such as the first photoactive semiconductor layer 108 and the tunnel junction layer 116, have been omitted.

Typically in acid, the photoelectrode is the cathode of the PEC cell, where protons are reduced to hydrogen, and the counter electrode is the anode, where water molecules are oxidized to oxygen and protons. Other possible configurations include using an n-type semiconductor as a photoanode coupled with a dark cathode, or where both anode and cathode are photoactive by coupling an n-type and p-type semiconductor, respectively. The anode typically comprises a noble metal (i.e., ruthenium, rhodium, palladium, silver, osmium, iridium, platinum or gold) or an alloy or oxide thereof to prevent corrosion due to harsh electrolytes. Nickel anodes may also be suitable if a basic electrolyte solution is used.

As shown in FIG. 1, the photoactive semiconductor layers 104 may be a multijunction/tandem cell system comprising multiple p-type or n-type Group III-V semiconductors, in addition to connections or junctions (e.g., tunnel junctions) between the cells. Tunnel junctions are solid-state connections (i.e., part of the monolithic device) that electrically connect two layers in series while having little or no optical absorption or electrical resistivity.

### EXAMPLES

### Example 1

### Surface Nitridation Conditions

A thin (2 μm) film of p-type, zinc (Zn)-doped (about 10¹⁸cm⁻³) GaInP₂ grown on a highly Zn-doped p-type GaAs substrate was nitrided by bombardment with low-energy N₂⁺ ions at room temperature in an evacuated chamber using an ion gun. Samples were treated for 30 seconds using a 3 cm Ion Tech gridded source at a distance of 8 inches and an angle of 55 degrees. The following additional conditions were used: nitrogen pressure: 7.0×10⁻⁴ Torr, source filament current: 3.21 A, discharge current: 0.22 mA, discharge voltage: 55 V, beam current: 12 mA, beam voltage: 550 V, accelerator current: 2 mA, accelerator voltage: 100 V, neutralizer current: 10 mA, and neutralizer filament current: 2.94 V.

### Example 2

### Sputtering Pt/Ru Alloy

Sputtering was accomplished in the same chamber as the surface nitridation by bringing the base chamber pressure up to 10 mTorr with argon gas. A 50:50 Pt/Ru sputter target was used and the DC sputtering power was set to 20 W and allowed to warm up for four minutes prior to sample treatment. The samples were treated by rotating the sample stage twice through the sputter plume at 15 rpm for a total exposure time of about 0.5 seconds.

### Example 3

### Effect of Semiconductor Treatment on Photoelectrode Function

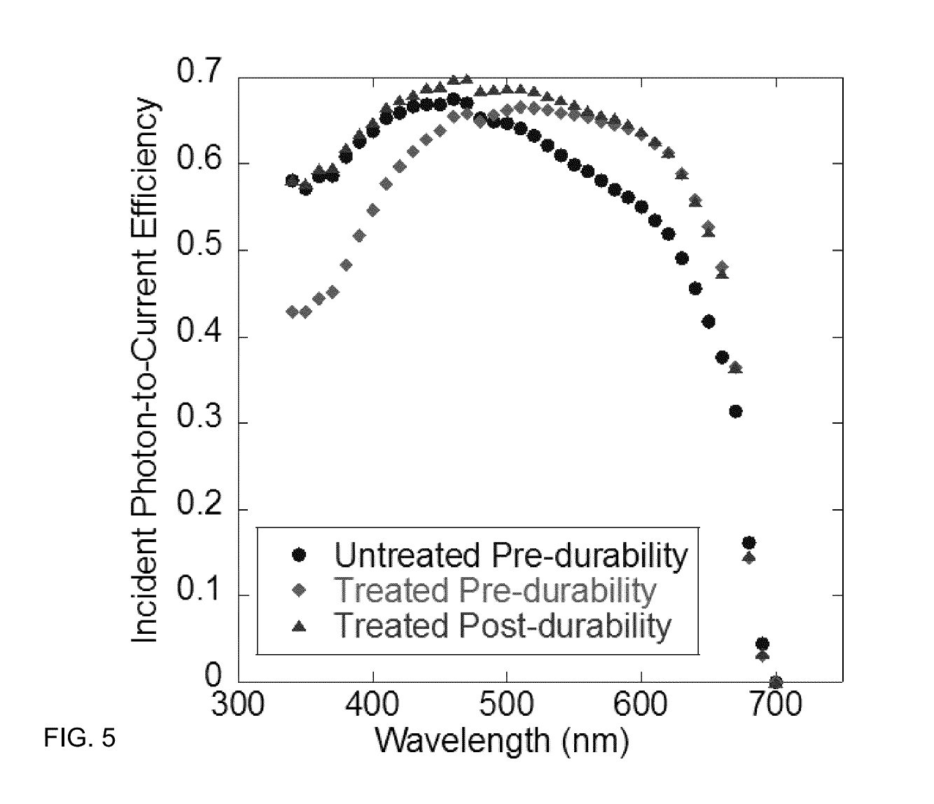

Treated p-type GaInP₂ samples were investigated by optical and electron microscopy and x-ray photoelectron spectroscopy (XPS). Respective PEC devices were characterized by incident photon-to-current efficiency (IPCE) and chopped-light voltammetry (J-V). The results were compared to those of control (untreated) samples of p-type GaInP₂. IPCE analysis (shown in FIG. 5) indicates that there is a loss in conversion efficiency of lower wavelength (higher energy) photons for the treated samples. This would be expected as these photons are absorbed closer to the surface and the ion implantation likely introduces surface defects that cause recombination of charge carriers photogenerated in this region. The losses here are offset by improved IPCE at wavelengths greater than 500 nm, and under calibrated white light, the treated electrode exhibits a higher light-limited photocurrent magnitude. After a typical 24-hour durability test, both the IPCE and light-limited photocurrent magnitude of the treated electrode improve. A possible explanation for these observations is that the ion implantation leaves broken, dangling bonds that act as recombination centers, and hydrogen evolution provides hydrogen atoms to passivate these bonds so that they are no longer trapping sites for photogenerated electrons and holes.

### Example 4

### Corrosion Durability Testing #1

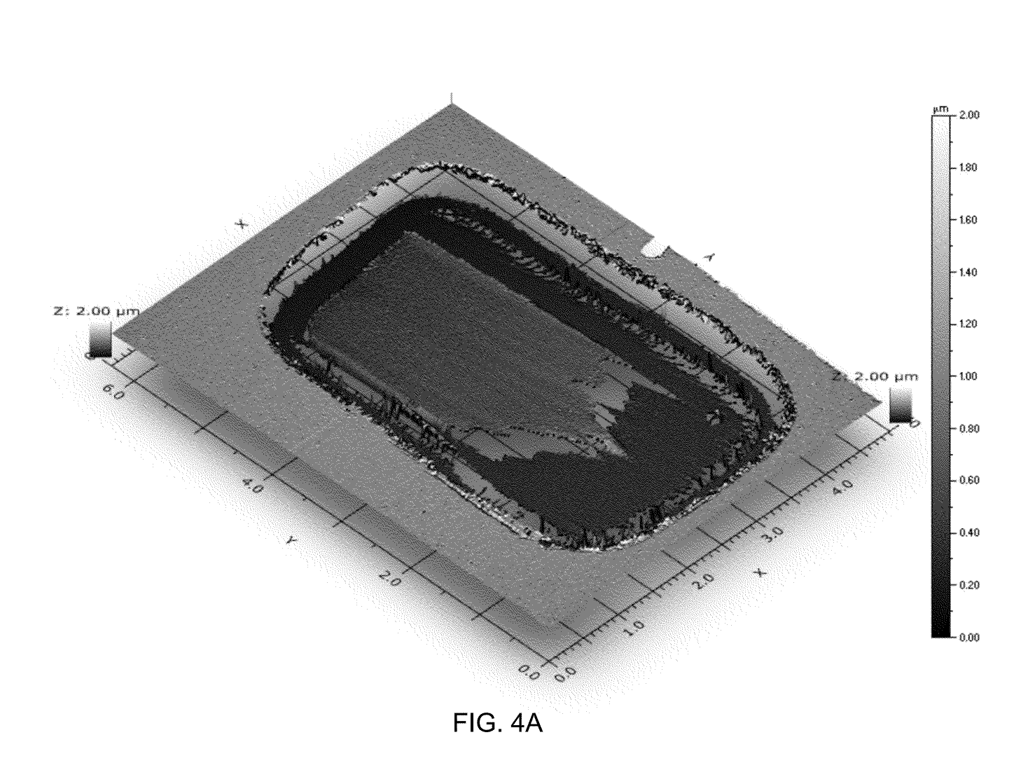

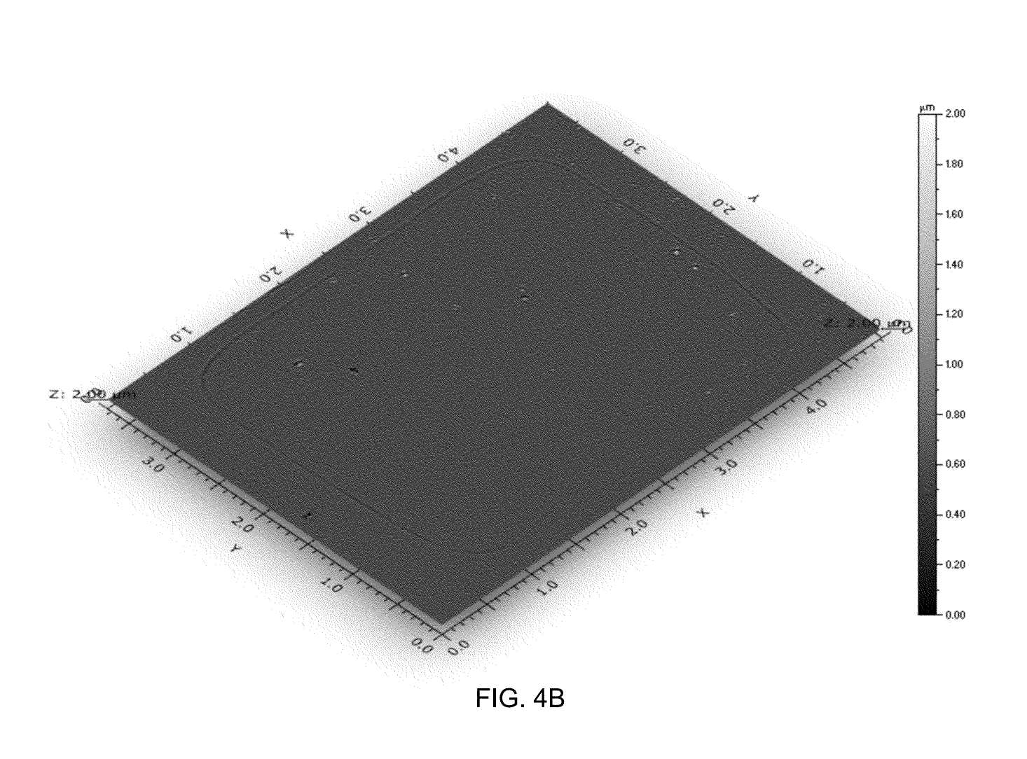

Treated (FIGS. 3A and 4A) and untreated (FIGS. 3B and 4B) samples were tested for durability in an aqueous electrolyte comprising sulfuric acid. A constant current of −10 mA/cm² was applied to each sample in an aqueous solution of 3M H₂SO₄ for 24 hours (or longer where noted) under AM1.5G illumination. The two-dimensional representations of the optical profilometry data for these samples are presented in FIG. 3. As can be seen, etching is seen in the untreated sample, but not the treated sample, after 24 hours. The three-dimensional optical profilometry data of the same samples is presented in FIG. 4, which again shows degradation of the untreated, but not the treated, sample after 24 hours.

Three-electrode J-V data was collected following durability testing to assess photoelectrode performance. After the durability tests, the respective electrolytes were analyzed by inductively coupled plasma mass-spectrometry (ICP-MS) to determine concentrations of indium and gallium in solution to quantify semiconductor corrosion. Optical profilometry was also used to measure the volume of material lost from the surface due to corrosion during operation. X-ray photoelectron spectroscopy (XPS) and X-ray emission spectroscopy (XES) results indicated that the surfaces of nitrided p-GalnP₂ samples contain nitrogen in a chemical environment characteristic of a nitride (e.g., GaN). Some of the nitrided samples entirely resisted corrosion over 24 or even 115 hours of testing, where similarly tested untreated samples experienced material loss from their surfaces of around 1 μm in depth (see FIG. 4A).

The results of ICP-MS analyses are shown in FIG. 6. ICP-MS detected a greater amount of gallium and indium in solution for untreated electrodes (A1-A4) than from electrodes made from two separate treatment runs of p-GaInP₂ (B1-B3) and (C1-C3). Typical Ga and In concentrations detected were about 1 ppm for untreated samples and 15 ppb (or 0.015 ppm) for treated electrodes. Because the electrolyte volume and surface areas were slightly variable between electrodes, the values were normalized to allow inter-comparison—parts per billion (ppb) was converted to nanomoles to normalize for varying solution volumes and the overall Coulombs passed was used to normalize for variable surface areas.

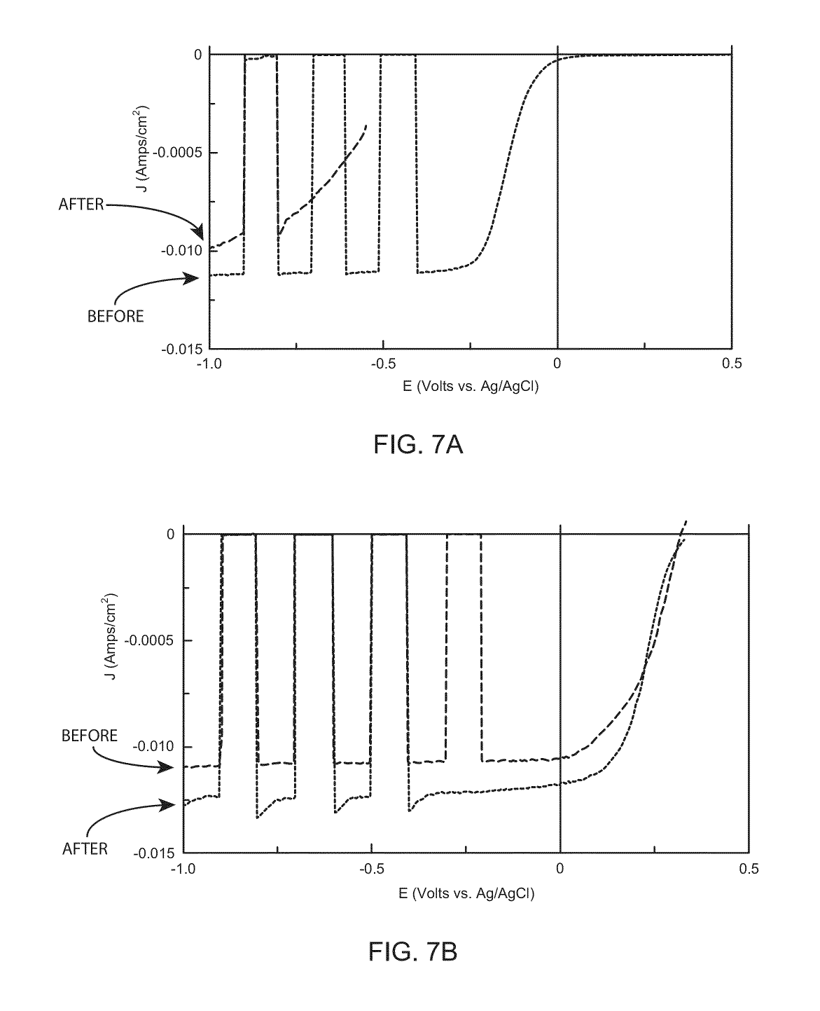

In addition to preventing physical degradation of the semiconductor after extended durability testing, the treatment also prevents any loss in photoelectrochemical performance. FIG. 7 shows chopped-light, three-electrode J-V data taken in 3M H₂SO₄ with light calibrated to AM 1.5G before and after durability testing. The appearance of dark current, reduced magnitude of light-limited photocurrent, and negative shift in photocurrent onset potential in FIG. 7A are common features of an electrode that has succumbed to corrosion. The treated electrode in FIG. 7B does not exhibit any of these features and the light-limited photocurrent magnitude actually improves after extended testing.

### Example 5

### Corrosion Durability Testing #2

The purpose of the testing performed for this Example was to demonstrate durability up to 24 hours of continuous hydrogen evolution operating at ˜25 mA/cm2 under 1 sun illumination by applying optimized nitrogen ion implantation surface passivation treatment to p-InP semiconductors with a bandgap of 1.33 eV. As set forth below, the data established that the passivation treatment is effective on a III-V semiconductor that, with the development of the proper tandem structure, is capable of achieving 25% solar-to-hydrogen conversion efficiency.

A protective surface modification (nitrogen implantation and/or PtRu or Ru sputtering) was applied to p-InP in the manner described in Examples 1 and 2. Dramatically improved photocorrosion resistance was observed in the treated/protected semiconductor surfaces as compared to non-treated surfaces. The observed bandgap of InP was 1.33 eV, compared with 1.81 eV for GaInP₂, allowing greater utilization of the solar spectrum and higher theoretical solar-to-hydrogen (STH) efficiencies in an optimized tandem configuration. Out of twenty-one treated p-InP electrodes tested at −25 mA/cm² for 24 hours, seventeen had no visible signs of degradation and only trace quantities of indium (˜25ppb) in their durability electrolytes. Of the fifteen samples that were treated with PtRu, 93% of the samples were successfully protected from corrosion. Conversely, similarly tested untreated p-InP samples had several microns of material removed from their surfaces and indium concentrations in durability electrolytes greater than two orders of magnitude higher than the treated electrodes (˜4 ppm vs. ˜25 ppb). These results demonstrate that III-V surfaces treated according to the methods disclosed herein can be protected against corrosion under the high flux conditions that accompany high-efficiency targets of 25% STH.

A 4-μm thick p-InP epilayer was synthesized by metal organic chemical vapor deposition. The wafer was subdivided into four quarters. One of the four quarters received nitrogen ion implantation followed by a PtRu alloy sputtering, in the same manner described in Examples 1 and 2. Two of the other quarters received only a sputtering treatment, one with PtRu and the other with Ru alone. The fourth was left untreated. Each quarter was then cut into smaller pieces and mounted to make electrodes with surface areas on the order of 0.1 cm². Photoelectrodes were galvanostatically tested for durability in 3M H₂SO₄ electrolytes, with the fluorosurfactant ZONYLO FSN-100, and with the galvanostat maintaining a constant photocurrent density of −25 mA/cm² for 24 hours. Electrodes were illuminated by a 250-Watt tungsten light source calibrated to AM1.5 G with a 1.1 eV band gap Si reference cell. All of the tests were performed in a two-terminal configuration, with water oxidation occurring at a platinum counter electrode.

After the 24-hour tests, the electrodes were deconstructed and the semiconductor surfaces were qualitatively evaluated with low-magnification optical photomicroscopy. The degree of surface etching was also determined with optical profilometry. Inductively coupled plasma mass spectrometry (ICP-MS) was used to quantitatively assess indium concentrations in the electrolytes used for each durability test. The analytes were detected in ppb quantities and converted to nanomoles per Coulomb to account for variations in testing cell volume and electrode surface area.

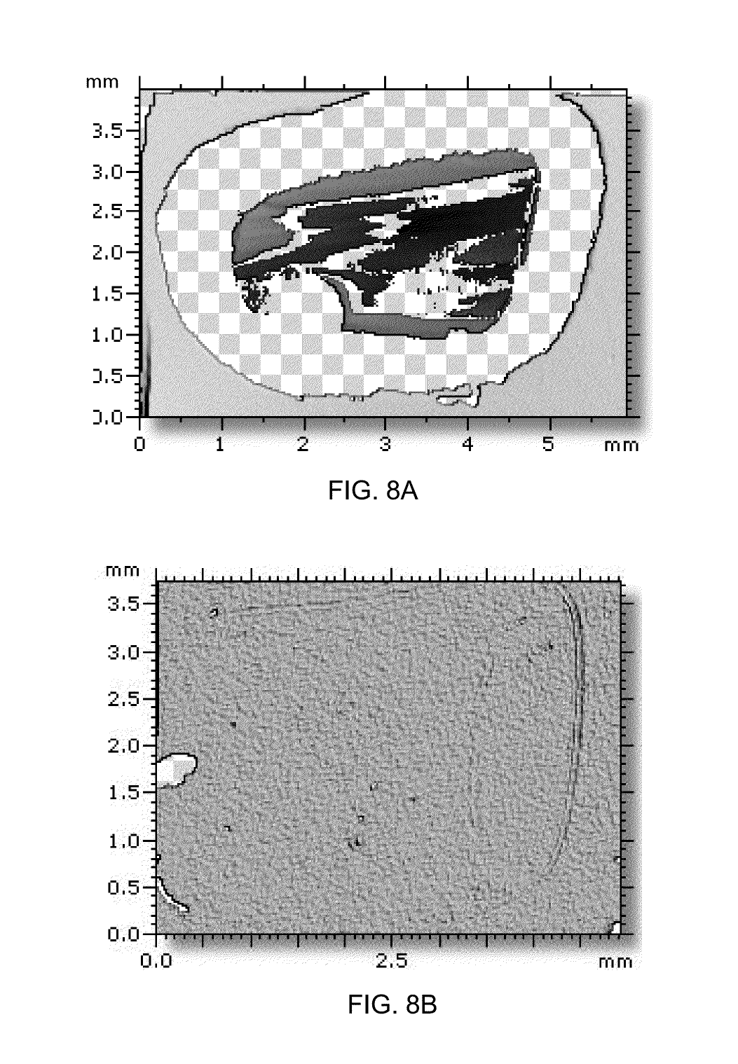

At the conclusion of the durability testing, all of the untreated semiconductor electrodes and four of the treated electrodes exhibited dramatically altered surfaces. FIG. 8A and FIG. 8B are two-dimensional representations of optical profilometry data for p-InP surfaces after 24 hours of testing at 25 mA/cm² in 3M H₂SO₄. The checkerboard areas in the images correspond to the metallic looking areas of the surface where diffuse reflection prevented the instrument from collecting z-axis data. The electrode in FIG. 8A was untreated and displayed significant damage in the area exposed to the electrolyte. The electrode in FIG. 8B was surface protected by nitrogen ion implantation and PtRu sputtering and displayed no obvious difference between the area exposed to the electrolyte and the portion masked by epoxy during testing. All of the “failed” electrodes had a similar appearance, with the surface transformed from a specular reflective smooth appearance to a metallic looking surface (FIG. 8A) in the electrochemically active areas. Most of the treated electrodes had no obvious signs of degradation, with surfaces similar to the one shown in FIG. 8B.

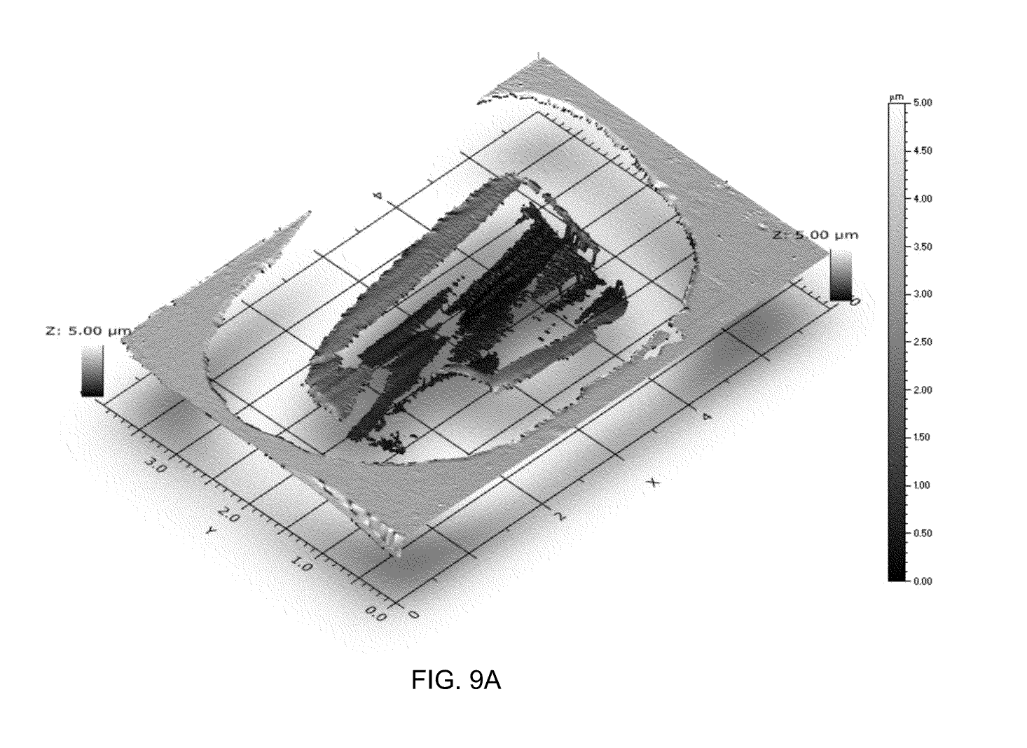

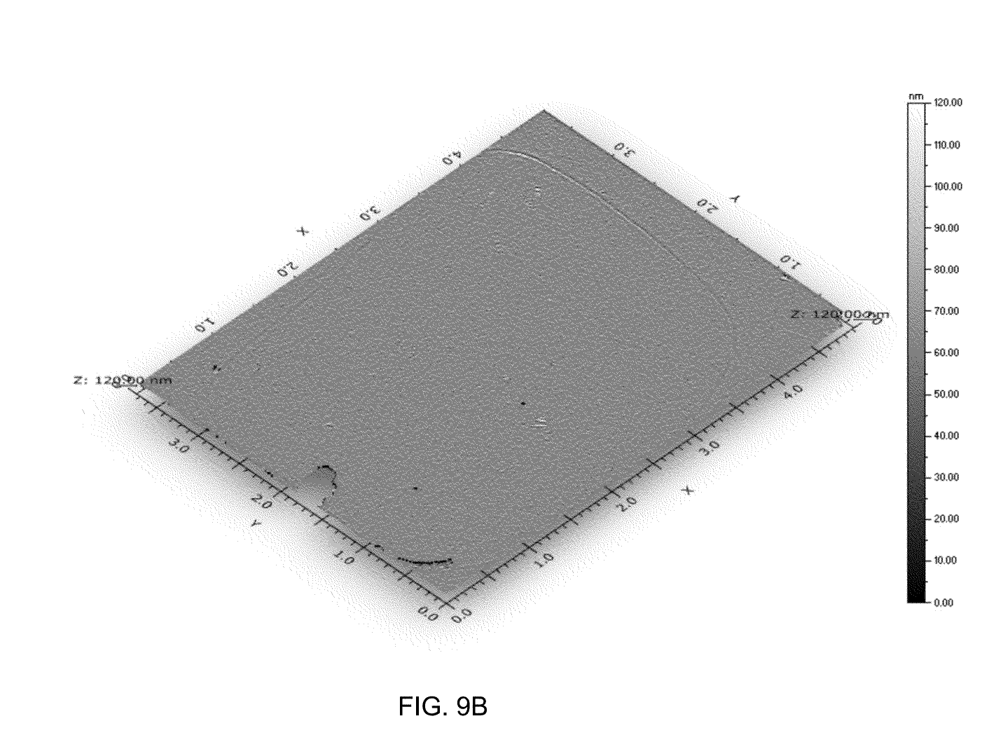

FIG. 9A and FIG. 9B are optical interference profilometries of p-InP surfaces after 24 hours of testing at 25 mA/cm² in 3M H₂SO₄. The electrode in FIG. 9A was untreated and had 3-4 μm of InP removed from the area exposed to the electrolyte. The electrode in FIG. 9B was surface protected by nitrogen ion implantation and PtRu sputtering and displayed no obvious difference between the exposed area and the portion masked by epoxy during testing.

The physical degradation that was apparent on the failed electrodes was confirmed with optical profilometry. The electrodes that failed experienced removal of 3-4 μm of InP from their surfaces (FIG. 9A) over the course of the durability testing. Optical profilometry was unable to detect any etching on electrodes that were subjected to surface protection via the methods disclosed herein. The area exposed to electrolyte was indistinguishable from the native surface, with both having features varying by only a few nanometers. The image in FIG. 9A is the same untreated electrode depicted in FIG. 8A. The image in FIG. 9B was a nitrogen ion implanted and PtRu sputtered electrode and exhibited a RMS surface roughness of only 3 nm after durability testing.

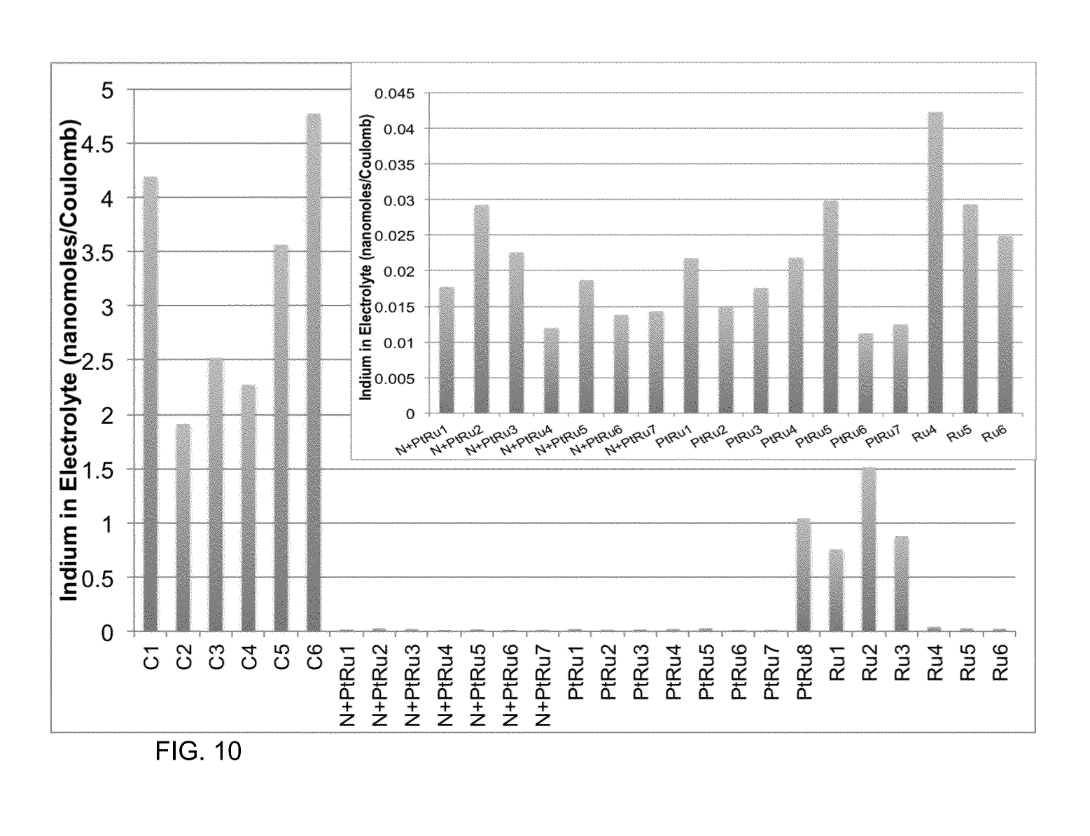

FIG. 10 is a bar graph that shows the concentration of indium present in 3M H₂SO₄ durability solutions as detected by ICP-MS for InP electrodes that were untreated (C), nitrogen ion implanted and PtRu sputtered (N+PtRu), PtRu sputtered only (PtRu), and Ru sputtered only (Ru). Lower values for the treated electrodes compared with the untreated samples confirm qualitative stability observations. Electrode N+PtRu5 corresponds to the image of the surface protected sample shown in FIG. 8B.

The concentration of indium detected in durability electrolytes by ICP-MS correlated well with the degree of degradation observed (FIG. 10). The normalized indium values for the controls and treated electrodes that failed were well above the others that had no obvious signs of corrosion. Of the twenty-one treated electrodes tested, one electrode treated with PtRu only and three electrodes treated with Ru only failed. The inset of FIG. 10 shows all of the successfully protected electrodes and there was no obvious difference between electrodes with N-ion implanted and PtRu sputtered and PtRu sputtered only. The Ru sputtered only electrodes displayed normalized indium values that were slightly higher than the other two treatments, but well below the untreated electrodes. The failure rate of the Ru only electrodes was 50%, suggesting that the addition of platinum in the sputtering process is an advantageous component of a successful surface passivation treatment. Of the fifteen treatments that incorporated PtRu sputtering, only one failed, resulting in 93% of the electrodes successfully resisting corrosion under these testing conditions. None of the N+PtRu electrodes failed, they all survived testing. The data indicate that PtRu sputtering coupled with N-ion implantation provide strong protection for electrodes.

Example 6

Water Splitting

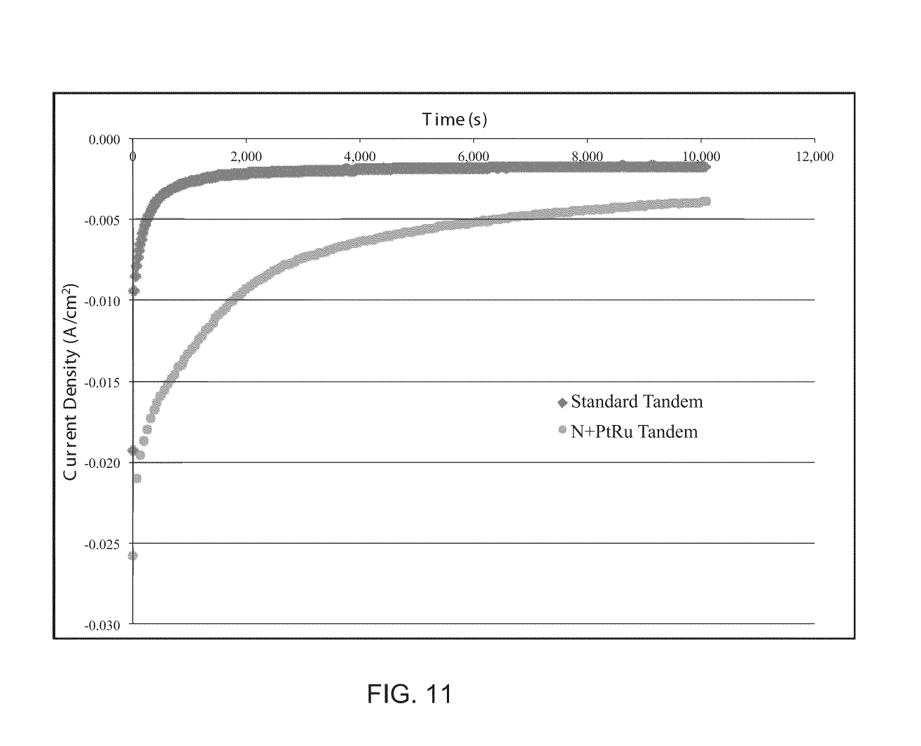

FIG. 11 is a graph of true short circuit zero-bias photocurrent density vs. time, comparing a standard GaInP₂/GaAs tandem with platinum electrodeposited on its surface, and a nitrogen ion implanted and PtRu sputtered GaInP₂/GaAs tandem. The negative current corresponded to the reduction of protons (hydrogen evolution) at the semiconductor working electrode. The working electrodes were shorted to platinum black counter electrodes where oxygen was generated by the oxidation of water. These tests were performed in 3M H₂SO₄ with ZONYL® FSN-100 fluorosurfactant under simulated AM1.5 G illumination from a tungsten light source. The magnitude of the current was directly proportional to the rate of water splitting. The N+PtRu tandem started at and maintained a higher water splitting efficiency than the standard tandem.

The Examples discussed above are provided for purposes of illustration and are not intended to be limiting. Other embodiments and modifications are also contemplated and are to be considered within the scope of the Examples provided herein.

While a number of examples of aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

We claim:

1. A method of treating an exposed semiconductor surface, comprising:
implanting nitrogen ions in the exposed semiconductor surface; and
depositing a ruthenium alloy on the exposed semiconductor surface.

2. The method of claim 1, wherein the ruthenium alloy comprises ruthenium and platinum.

3. The method of claim 2, wherein the ruthenium alloy comprises ruthenium and platinum at a 50:50 ratio.

4. The method of claim 1, wherein the ruthenium alloy is deposited in a submonolayer amount.

5. The method of claim 1, wherein the ruthenium alloy is deposited on the exposed semiconductor surface as nanoparticles.

6. The method of claim 5, wherein the nanoparticles are about 2-5 nm in diameter.

7. The method of claim 1, wherein the semiconductor comprises a Group III-V semiconductor.

8. The method of claim 7, wherein the Group III-V semiconductor comprises GaInP₂.

9. The method of claim 8, wherein the Group III-V semiconductor comprises p-type GaInP₂.

10. The method of claim 7, wherein the Group III-V semiconductor comprises InP.

11. The method of claim 10, wherein the Group III-V semiconductor comprises p-type InP.

12. The method of claim 1, wherein the step of implanting and the step depositing are conducted in the same chamber.

13. A photoelectrode, comprising:
a nitrided semiconductor; and
a submonolayer amount of a ruthenium alloy in contact with at least one surface of the nitrided semiconductor.

14. The photoelectrode of claim 13, wherein the ruthenium alloy comprises ruthenium and platinum.

15. The photoelectrode of claim 13, wherein the semiconductor is a Group III-V semiconductor.

16. The photoelectrode of claim 15, wherein the Group III-V semiconductor comprises GaInP₂.

17. The photoelectrode of claim 15, wherein the Group III-V semiconductor comprises InP.

18. A photoelectrochemical cell, comprising:
a photoelectrode including a nitrided semiconductor; and
a submonolayer amount of a ruthenium alloy in contact with at least one surface of the nitrided semiconductor.

19. The photoelectrochemical cell of claim 18, wherein the ruthenium alloy comprises ruthenium and platinum.

20. The photoelectrochemical cell of claim 18, wherein the semiconductor is a Group III-V semiconductor.
